(19) United States
(12) Patent Application Publication
(10) Pub. No.: US 2013/0214392 A1
(43) Pub. Date: Aug. 22, 2013

(54) METHODS OF FORMING STEPPED ISOLATION STRUCTURES FOR SEMICONDUCTOR DEVICES USING A SPACER TECHNIQUE

(71) Applicants: Stephan Kronholz, Dresden (DE); Jorg Radecker, Dresden (DE); Hans-Juergen Thees, Dresden (DE); Peter Javorka, Radeburg (DE)

(72) Inventors: Stephan Kronholz, Dresden (DE); Jorg Radecker, Dresden (DE); Hans-Juergen Thees, Dresden (DE); Peter Javorka, Radeburg (DE)

(73) Assignee: GLOBALFOUNDRIES INC., Grand Cayman (KY)

(21) Appl. No.: 13/400,422

(22) Filed: Feb. 20, 2012

(51) Int. Cl. H01L 29/06; H01L 21/762

(52) U.S. Cl. 257/622; 438/427; 257/E21.548; 257/E29.02

(57) ABSTRACT

Disclosed herein are various methods of forming stepped isolation structures for semiconductor devices using a spacer technique. In one example, the method includes forming a first trench in a semiconducting substrate, wherein the first trench has a bottom surface, a width and a depth, the depth of the first trench being less than a target final depth for a stepped trench isolation structure, performing an etching process through the first trench on an exposed portion of the bottom surface of the first trench to form a second trench in the substrate, wherein the second trench has a width and a depth, and wherein the width of the second trench is less than the width of the first trench, and forming the stepped isolation structure in the first and second trenches.

### BACKGROUND OF THE INVENTION

1. Field of the Invention

Generally, the present disclosure relates to the manufacturing of sophisticated semiconductor devices, and, more specifically, to various methods of forming stepped isolation structures, such as trench isolation structures, for semiconductor devices using a spacer technique.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit element used in manufacturing such integrated circuit devices. A field effect transistor, irrespective of whether an NMOS transistor or a PMOS transistor is considered, typically comprises doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

To make an integrated circuit on a semiconducting substrate, the various semiconductor devices, e.g., transistors, capacitors, etc., are electrically isolated from one another by so-called isolation structures. Currently, most sophisticated integrated circuit devices employ so-called shallow trench isolation (STI) structures. As the name implies, STI structures are made by forming a relatively shallow trench in the substrate and thereafter filling the trench with an insulating material, such as silicon dioxide. One technique used to form STI structures initially involves growing a pad oxide layer on the substrate and depositing a pad nitride layer on the pad oxide layer. Thereafter, using traditional photolithography and etching processes, the pad oxide layer and the pad nitride layer are patterned. Then, an etching process is performed to form trenches in the substrate for the STI structure using the patterned pad oxide layer and pad nitride layer as an etch mask. Thereafter, a deposition process is performed to overfill the trenches with an insulating material such as silicon dioxide. A chemical mechanical polishing (CMP) process is then performed using the pad nitride layer as a polish-stop layer to remove the excess insulation material. Then, a subsequent deglazing (etching) process may be performed to insure that the insulating material is removed from the surface of the pad nitride layer. This deglaze process removes some of the STI structures.

Numerous processing operations are performed in a very detailed sequence, or process flow, to form such integrated circuit devices, e.g., deposition processes, etching processes, heating processes, masking operations, etc. One problem that arises with current processing techniques is that, after the STI regions are formed, at least portions of the STI regions are exposed to many subsequent etching or cleaning processes that tend to consume, at least to some degree, portions of the STI structures subjected to such etching processes. As a result, the STI structures may not perform their isolation function as intended, which may result in problems such as increased leakage currents, etc. Furthermore, since the erosion of the STI structures is not uniform across a die or a wafer, such structures may have differing heights, which can lead to problems in subsequent processing operations. For example, such height differences may lead to uneven surfaces on subsequently deposited layers of material, which may require additional polishing time in an attempt to planarize the surface of such layer. Such additional polishing may lead to the formation of additional particle defects which may reduce device yields.

The present disclosure is directed to various methods of forming isolation structures that may eliminate or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming stepped isolation structures for semiconductor devices using a spacer technique. In one example, the method includes forming a first trench in a semiconducting substrate, wherein the first trench has a bottom surface, a width and a depth, the depth of the first trench being less than a target final depth for a stepped trench isolation structure, performing an etching process through the first trench on an exposed portion of the bottom surface of the first trench to form a second trench in the substrate, wherein the second trench has a width and a depth, and wherein the width of the second trench is less than the width of the first trench, and forming the stepped isolation structure in the first and second trenches.

Another illustrative method disclosed herein of forming a stepped trench isolation structure in a semiconducting substrate, the stepped trench isolation structure having a target final depth from an upper surface of the substrate, includes the steps of forming a first trench in a semiconducting substrate, wherein the first trench has sidewalls, a width and a depth, the depth of the first trench being less than a target final depth for a stepped trench isolation structure, and forming a sidewall spacer on the opposed sidewalls of the first trench, wherein the sidewall spacers define an opening. In this illustrative example, the method further includes performing an etching process on the substrate through the opening defined by the spacers to form a second trench in the substrate, wherein the second trench has a width and a depth, and wherein the width of the second trench is less than the width of the first trench, and forming the stepped isolation structure in the first and second trenches.

An illustrative device disclosed herein includes a semiconducting substrate, a stepped trench formed in the substrate, and a stepped isolation structure positioned in the stepped trench. In this illustrative example, the stepped trench comprises a first trench having a width and a depth, wherein the depth of the first trench is less than a target final depth for the stepped isolation structure relative to an upper surface of the substrate and a second trench, and a second trench having a width and a depth, wherein the width of the second trench is less than the width of the first trench and wherein the depth of second trench is at least equal to the target final depth of the stepped isolation structure less the depth of the first trench.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1J depict various novel methods disclosed herein for forming stepped isolation structures for semiconductor devices using a spacer technique.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

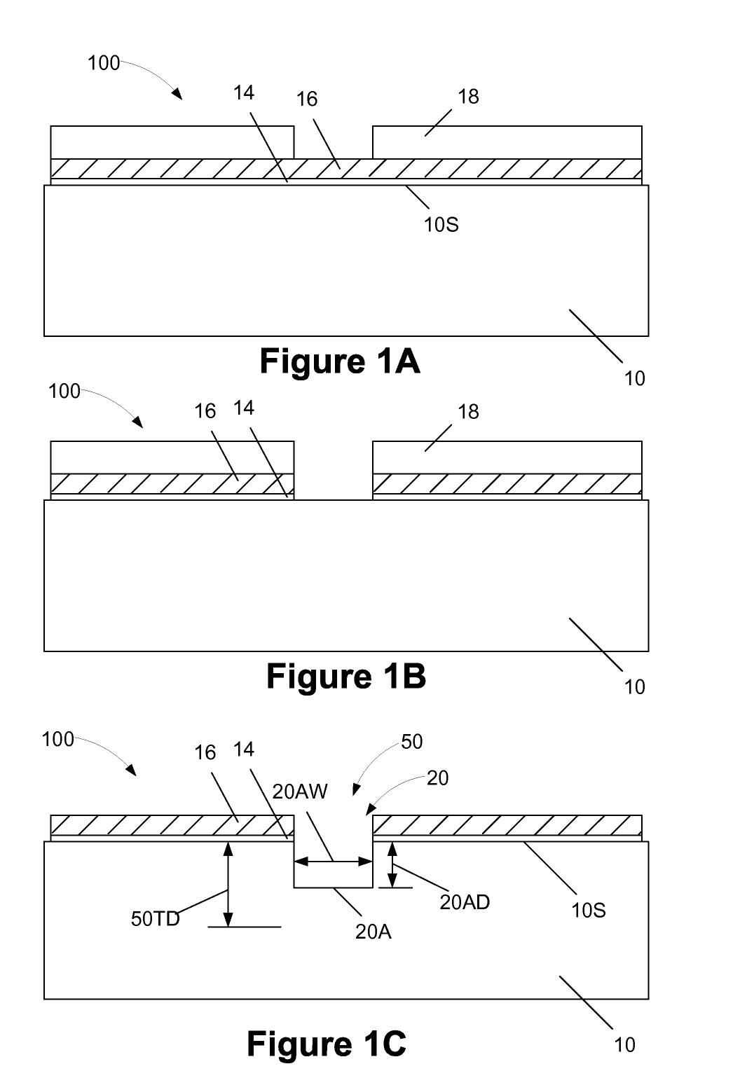

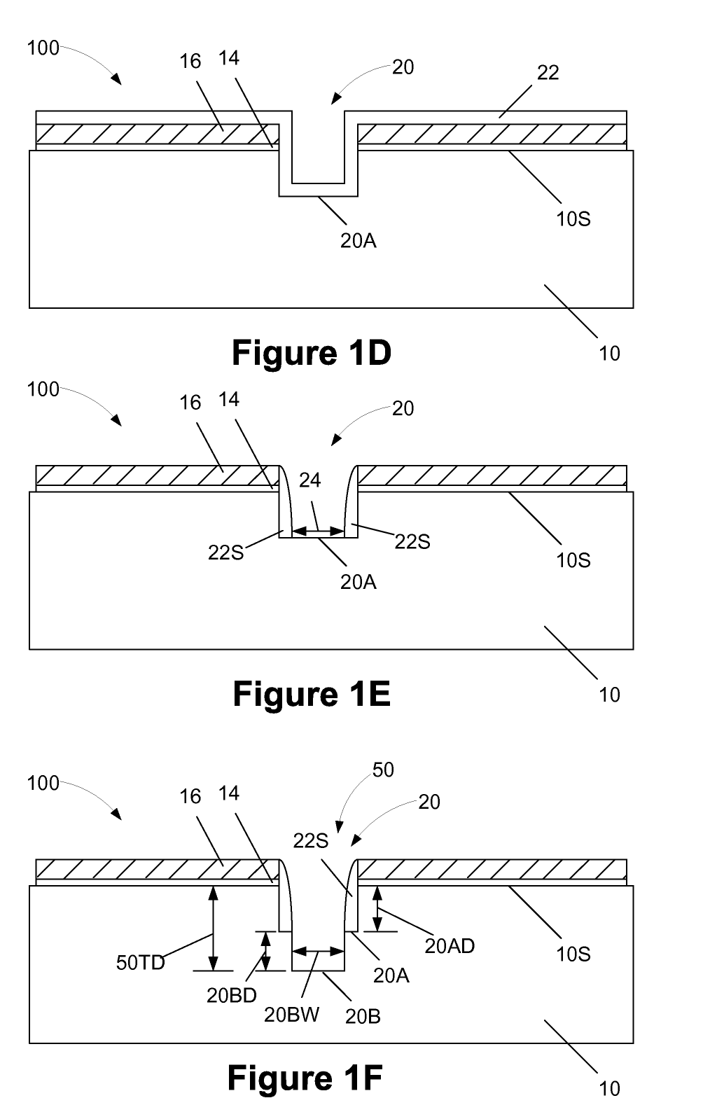

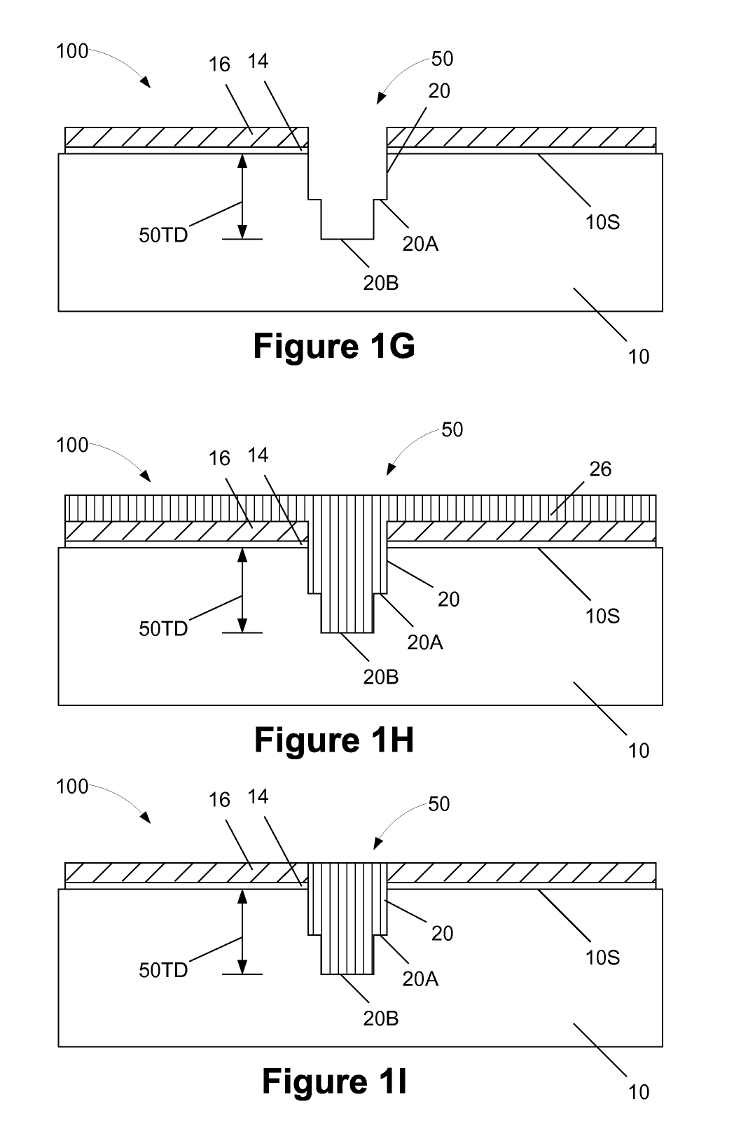

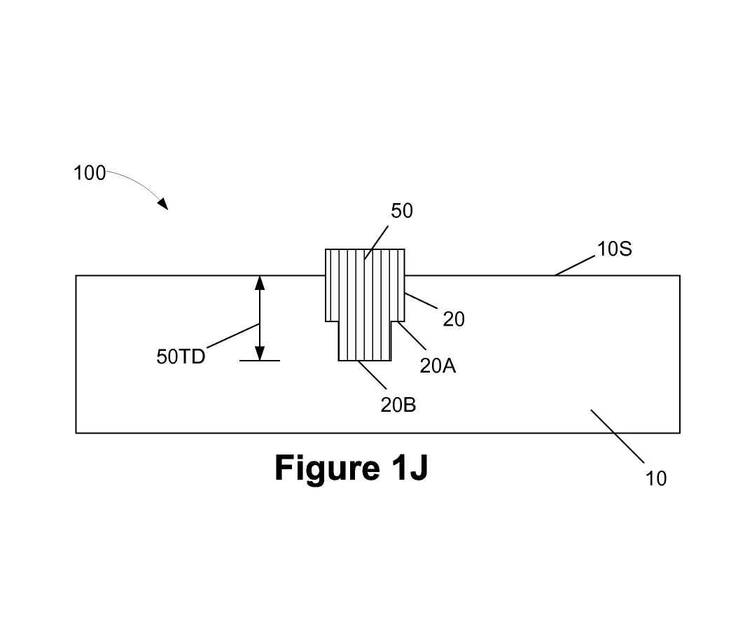

The present disclosure is directed to various methods of forming stepped isolation structures for semiconductor devices using a spacer technique. As will be readily apparent to those skilled in the art upon a complete reading of the present application, the present method is applicable to a variety of devices, including, but not limited to, logic devices, memory devices, etc. With reference to FIGS. 1A-1J, various illustrative embodiments of the methods and devices disclosed herein will now be described in more detail.

FIG. 1A is a simplified view of an illustrative semiconductor device 100 at an early stage of manufacturing. The semiconductor device 100 is formed above an illustrative bulk semiconducting substrate 10 having an upper surface 10S. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 10 may also be made of materials other than silicon.

In FIG. 1A, the device 100 is depicted at the point of fabrication where an illustrative protection layer 14, e.g., a screen or pad oxide layer, and a polish stop layer 16, e.g., a pad nitride layer, have been formed above the substrate 10. Also depicted in FIG. 1A is a patterned mask layer 18, e.g., a patterned photoresist mask that may be formed using traditional photolithography tools and techniques. In one illustrative example, the protection layer 14 may be a pad oxide layer having a thickness on the order of about 10 nm, and it may be formed by performing a thermal growth process. In one illustrative example, the polish stop layer 16 may be a pad nitride layer having a thickness on the order of about 80 nm, and it may be formed by performing a chemical vapor deposition (CVD) process.

Thereafter, as shown in FIG. 1B, an etching process, such as a reactive ion etching process, is performed through the mask layer 18 to pattern the protection layer 14 and the polish stop layer 16.

Ultimately, the device 100 will comprise a stepped trench isolation structure 50, having a target final depth 50TD, that will be formed in the substrate 10. In general, in the disclosed embodiment, formation of the stepped trench isolation structure 50 will involve performing multiple etching processes to form at least two partial depth trenches. FIG. 1C depicts the device 100 after the masking layer 18 has been removed and an etching process, such as an anisotropic reactive ion etching process, has been performed to form an initial trench 20A in the substrate 10 using the patterned protection layer 14 and polish stop layer 16 as an etch mask. The trench 20A has a width 20AW and a depth 20AD, each of which may vary depending on the particular application. In one illustrative example, the depth 20AD of the initial trench 20A may be approximately one-third to one-half of the target final depth 50TD of the stepped isolation structure 50. In one illustrative embodiment, in current day devices, the target final depth 50TD may range from about 30-500 nm, the width 20AW may range from about 10-100 nm and the depth 20AD may range from about 100-500 nm, although these illustrative examples may vary depending upon the particular application. For ease of illustration, the trenches 20A, 20B are depicted herein as having a generally rectangular cross-section. In real-world devices, the sidewalls of the trenches 20A, 20B will likely be somewhat inwardly tapered.

Next, as shown in FIG. 1D, a layer of spacer material 22 may be conformably deposited above the device and in the trench 20A. The layer of spacer material 22 may be comprised of a variety of materials that may be selectively etched with respect to the polish stop layer 16. For example, in the illustrative case where the polish stop layer 16 is comprised of silicon nitride, the layer of spacer material 22 may be comprised of silicon dioxide, silicon nitride, etc., it may have a thickness ranging from about 2-50 nm, and it may be formed by performing a variety of known processes, such as a chemical vapor deposition (CVD) process, an atomic layer deposition (ALD) process, or plasma-enhanced versions of such processes.

Next, as shown in FIG. 1E, an anisotropic etching process is performed on the layer of spacer material 22 to thereby define spacers 22S positioned on the sidewalls of the initial trench 20A. In one illustrative embodiment, the spacers 22S may have a base width that ranges from 2-50 nm, and the spacers 22S define a reduced size opening 24 that may range from about 26-296 nm. The opening 24 exposes a portion of the bottom surface of the trench 20A for further processing.

FIG. 1F depicts the device 100 after another etching process, such as an anisotropic reactive ion etching process, has been performed through the opening 24 to form a second trench 20B in the substrate 10 using the spacers 22S and the polish stop layer 16 as an etch mask. The trench 20B has a width 20BW and a depth 20BD, each of which may vary depending on the particular application. In one illustrative example, the final stepped isolation structure 50 will be formed by forming only the two illustrative trenches 20A, 20B depicted herein. In that illustrative example, the depth 20BD of the second trench 20B may be such that the target final depth 50TD for the stepped isolation structure 50 is reached or exceeded. In one illustrative embodiment, in current day devices, the width 20BW may range from about 10-100 nm and the depth 20BD may range from about 30-400 nm, although these illustrative examples may vary depending upon the particular application.

Next, as shown in FIG. 1G, an etching process is performed to remove the spacers 22S from the trench 20A. The etching process performed to remove the spacers 22S may be either a wet or dry etching process. The stepped configuration of the stepped trench 20 for the stepped isolation structure 50 can be clearly seen in this drawing.

Next, as shown in FIG. 1H, a deposition process is performed to form a layer of insulating material 26 on the device 100 and to over-fill the stepped trench 20. The layer of insulating material 26 may be comprised of a variety of different materials, such as, for example, silicon dioxide, etc., and it may be made using a variety of different processes, e.g., chemical vapor deposition (CVD), atomic layer deposition (ALD), etc., or plasma-enhanced versions of those processes. In one illustrative embodiment, the layer of insulating material 26 may be a silicon dioxide material made using a well-known HDP (High Density Plasma) process. Silicon dioxide material made using an HDP process will be referred to as an “HDP silicon dioxide.”

Next, as shown in FIG. 1I, a CMP process is then performed to remove the portions of the layer of insulating material 26 positioned above the surface of the polish stop layer 16. This results in the formation of the stepped isolation structure 50 in the stepped trench 20. Thereafter, an etching or deglazing process is performed to insure that the surface of the polish stop layer 16 is free of any remnants of the layer of insulating material 26. This deglaze process may reduce the thickness of the stepped isolation structure 50 slightly, but such thickness reduction is not depicted in FIG. 1I. Then, as shown in FIG. 1J, one or more etching processes, wet or dry, are performed to remove the polish stop layer 16 and the protective layer 14.

In the depicted example, the novel methods disclosed herein provide efficient methods of forming STI structures, such as the illustrative stepped STI structure 50, even in high-aspect ratio applications where formation of traditional STI structures may be very challenging. That is, by initially forming a relatively wider, partial final depth trench, the aspect ratio of the stepped trench 20, prior to forming an insulating material therein, is effectively reduced, thereby facilitating the formation of an isolation structure in a more reliable and efficient manner.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention.

Accordingly, the protection sought herein is as set forth in the claims below.

What is claimed:

1. A method of forming a stepped trench isolation structure in a semiconducting substrate, said stepped trench isolation structure having a target final depth from an upper surface of said substrate, the method comprising:
forming a first trench in said semiconducting substrate, said first trench having a bottom surface, a width and a depth, said depth of said first trench being less than said target final depth;
performing an etching process through said first trench on an exposed portion of said bottom surface of said first trench to form a second trench in said substrate, said second trench having a width and a depth, wherein said width of said second trench is less than said width of said first trench; and
forming said stepped isolation structure in said first and second trenches.

2. The method of claim 1, wherein forming said stepped isolation structure in said first and second trenches comprises depositing a layer of insulating material so as to overfill said first and second trenches and performing a chemical mechanical polishing process to remove excess portions of said layer of insulating material.

3. The method of claim 1, wherein said depth of said first trench and said depth of said second trench, when combined, is at least equal to said target final depth of said stepped isolation structure.

4. The method of claim 1, wherein forming said first trench in said semiconducting substrate comprises performing an anisotropic etching process through a patterned polish stop layer to form said first trench.

5. The method of claim 1, wherein, prior to performing said etching process through said first trench on said exposed portion of said bottom surface of said first trench to form said second trench in said substrate, forming a sidewall spacer on opposed sidewalls of said first trench, side sidewall spacers defining an opening that exposes said portion of said bottom surface of said first trench.

6. The method of claim 1, wherein performing said etching process through said first trench on an exposed portion of said bottom surface of said first trench comprises performing an anisotropic etching process through said first trench to form said second trench.

7. A method of forming a stepped trench isolation structure in a semiconducting substrate, said stepped trench isolation structure having a target final depth from an upper surface of said substrate, the method comprising:
forming a first trench in said semiconducting substrate, said first trench having sidewalls, a width and a depth, said depth of said first trench being less than said target final depth;
forming a sidewall spacer on opposed sidewalls of said first trench, said sidewall spacers defining an opening;
performing an etching process on said substrate through said opening defined by said spacers to form a second trench in said substrate, said second trench having a width and a depth, wherein said width of said second trench is less than said width of said first trench; and
forming said stepped isolation structure in said first and second trenches.

8. The method of claim 7, wherein forming said stepped isolation structure in said first and second trenches comprises depositing a layer of insulating material so as to overfill said first and second trenches and performing a chemical mechanical polishing process to remove excess portions of said layer of insulating material.

9. The method of claim 8, wherein said depth of said first trench and said depth of said second trench, when combined, is at least equal to said target final depth of said stepped isolation structure.

10. The method of claim 8, wherein forming said sidewall spacer on said opposed sidewalls of said first trench comprises:
conformably depositing a layer of spacer material on at least said opposed sidewalls of said first trench; and
performing an anisotropic etching process on said layer of spacer material to define said sidewall spacers.

11. A method of forming a stepped trench isolation structure in a semiconducting substrate, said stepped trench isolation structure having a target final depth from an upper surface of said substrate, the method comprising:
performing an anisotropic etching process to form a first trench in said semiconducting substrate, said first trench having sidewalls, a width and a depth, said depth of said first trench being less than said target final depth;
forming a sidewall spacer on opposed sidewalls of said first trench, said sidewall spacers defining an opening;
performing an anisotropic etching process on said substrate through said opening defined by said spacers to form a second trench in said substrate, said second trench having a width and a depth, wherein said width of said second trench is less than said width of said first trench and said depth of said second trench is at least equal to said target final depth less said depth of said first trench;
depositing a layer of insulating material so as to overfill said first and second trenches; and
performing a chemical mechanical polishing process to remove excess portions of said layer of insulating material.

12. The method of claim 11, wherein depositing said layer of insulating material comprises performing a high density plasma (HDP) deposition process to deposit a layer of HDP silicon dioxide.

13. A device, comprising:
a semiconducting substrate;
a stepped trench formed in said substrate; and
a stepped isolation structure positioned in said stepped trench, said stepped trench comprising:
a first trench having a width and a depth, said depth of said first trench being less than a target final depth for said stepped isolation structure relative to an upper surface of said substrate; and
a second trench, said second trench having a width and a depth, wherein said width of said second trench is less than said width of said first trench and said depth of said second trench is at least equal to said target final depth of said stepped isolation structure less said depth of said first trench.

14. The device of claim 13, wherein said stepped isolation structure is comprised of high density plasma (HDP) silicon dioxide.
